(19) United States
(12) Patent Application Publication
(10) Pub. No.: US 2018/0254747 A1
(43) Pub. Date: Sep. 6, 2018

(54) DOHERTY AMPLIFIER

(71) Applicant: SUMITOMO ELECTRIC DEVICE INNOVATIONS, INC., Yokohama-shi (JP)

(72) Inventor: James WONG, Surrey (GB)

(73) Assignee: SUMITOMO ELECTRIC DEVICE INNOVATIONS, INC., Yokohama-shi (JP)

(21) Appl. No.: 15/907,852

(22) Filed: Feb. 28, 2018

Related U.S. Application Data
(60) Provisional application No. 62/465,529, filed on Mar. 1, 2017.

(51) Int. Cl. H03F 1/02; H03F 3/189; H03F 1/56; H03F 3/60

(52) U.S. Cl. CPC H03F 1/0288; H03F 3/189; H03F 1/56; H03F 2200/451; H03F 2200/387; H03F 2200/423; H03F 2200/543; H03F 3/602

(57) ABSTRACT

A Doherty amplifier stably operable even when an output thereof is smaller than the back-off level is disclosed. The Doherty amplifier installs a peak amplifier that shows a substantial leak due to parasitic components thereof when the output thereof is smaller than the back-off level. The peak amplifier is connected with the combining node through an impedance line whose impedance is higher than characteristic impedance. The carrier amplifier, which has characteristic same with the peak amplifier, is coupled with the combining node through a quarter wavelength line. The peak amplifier and the carrier amplifier have no output matching circuits therein.

### CROSS REFERENCE TO RELATED APPLICATION

The present application claims the priority under 35 U.S.C. § 119 of U.S. Provisional Application Ser. No. 62/465,529, filed on Mar. 1, 2017, the contents of which is relied upon and incorporated herein by reference in its/their entirety.

### BACKGROUND OF INVENTION

### 1. Field of Invention

The present invention relates to a Doherty amplifier.

### 2. Background Arts

Higher demand for data rates as increasing end-users to ensure seamless usage on mobile phones has requested to adopt further complex forms of signal algorithms, which results in modern mobile signals having extremely large Peak-to-Average signal ratios (PAR). However, when an amplifier architecture applied thereto is neither suitable nor capable of efficiently amplifying such signals to the end-users, an amplifier implemented therein would result in large thermal dissipation and energy consumption. There is currently a practical limit to implementation of such complex signal formats due to hardware limitations, for instance operable speed of Field Programmable Gate Array (FPGA), Digital to Analog Converter (DAC), Analog to Digital Converter (ADC), and so on.

In order to address the increasing demand for supporting user capacity, mobile operators have adopted the simplest and a most cost efficient solution of increasing the spectral power. As a result, amplifier solutions need to be able to provide both average power and efficiency, as well and addressing the large signal peaks.

In order to address high powers (average and peak); an ideal and simple solution is to use a transistor having an enhanced die size. Unfortunately, a transistor with an enhanced die size inherently has subjects below to be solved:
(a) Low impedance and larger parasitic components for impedance matching; and
(b) Thermal handling (dissipation) of transistor packages.

Effective thermal dissipation of the transistor chip itself has serious challenges and extremely large transistor devices, for instance, the power consumption thereof greater than 500 W in the single-ended from, is almost impossible to be available in the market. Amplifier designers are limited to select devices and architectures to address the power (average and peak) demands.

Considering a requirement of an average power of 100 W, with a signal PAR of 10, the amplifier architecture needs to be capable to be operable up to 1 kW in RF power. As mentioned above, no known transistor devices/dies in single-ended form in excess of 500 W is available in the market. Table below illustrates the options (prior arts) based on existing largest transistor device/die in single-ended form that are operable in excess 250 W.

| | Efficiency | | |
|---|---|---|---|
| Prior Art | (Average) | Gain | Comments |
| power combining | poor | best | Gain is similar to a |
| single-ended devices | | | single-ended class AB |
| | | | amplifier. Practical |
| | | | combining and splitting |
| | | | losses will contribute |
| | | | further to poor |
| | | | efficiency. |
| Symmetrical | medium | −3 dB | Gain is reduced by −3 dB; |
| Doherty: | good | | inherent Doherty |
| 2 × 250 W Carrier + | | | Architecture Complexity |
| 2 × 250 W Peak | | | with low impedances and |
| | | | matching. |
| Power Combining | medium | −3 dB | Performance if further |
| Doherty: | poor | | reduced due to the |
| 2 × (250 W Carrier + | | | unsymmetrical AM-AM |
| 250 W Peak) | | | AM-PM characteristics of |
| | | | each Doherty Amplifier. |
| 4-Way Doherty | good | −6 dB | Gain is reduced by 6 dB |
| 1 × 250 W Carrier + | | | due to 4-Way |
| 3 × 250 W Peak | | | architecture. |
| | | | Additional complexity |
| | | | with gate bias control. |
| Classical 3-way | good | −4.8 dB | Gain is reduced by −4.8 |
| Doherty | | | dB due to inherent 3-way |
| 1 × 200 W Carrier + | | | architecture. Increased |
| 2 × (2 × 200 W Peak) | | | complexity with low |
| | | | impedance (Peak) and |
| | | | gate bias control. |
| 3-way Doherty | good | −4.8 dB | Increased complexity |
| 1 × (2 × 165 W Carrier) + | | | with low impedance |
| 2 × (2 × 165W Peak) | | | (Peak) and gate bias |
| | | | control |

### SUMMARY OF INVENTION

An aspect of the present invention relates to a Doherty amplifier. The Doherty amplifier has a back-off level that is smaller than a present amount from saturated power in an output thereof. The Doherty amplifier includes a carrier amplifier (CA), a peak amplifier (PA), a combining node, a transmission line, and a impedance line. The CA, which amplifies an input RF signal, saturates output power thereof at the back-off level. The PA, which has characteristics identical with the CA, is configured to show a substantial leak when the Doherty amplifier shows an output thereof smaller than the back-off level. The PA saturates output power thereof at the saturated power. The combining node combines an output of the CA with the PA. The transmission line, which is provided between the CA and the combining node, has an electrical length of π/2 radian, namely, a quarter-wavelength (λ/4) of the input RF signal. A feature of the Doherty amplifier of the present invention is that the impedance line increases impedance viewing the peak amplifier from the combining node when the Doherty amplifier in the output power thereof is smaller than the back-off level.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows a functional block diagram of a Doherty amplifier according to an embodiment of the present invention;

FIG. 2 shows a relation of impedance of amplifiers a combining node when the Doherty amplifier generates a maximum power;

FIG. 3A shows measured output characteristics of the Doherty amplifier that covers 2.11 to 2.17 GHz of the present embodiment, and FIG. 3B shows measured output characteristics of the Doherty amplifier that covers 1.805 to 2.17 GHz;

FIG. 4 is a plan view showing the Doherty amplifier of the present embodiment; and

FIG. 5 schematically illustrates an inside of amplifiers implemented in the Doherty amplifier of the present invention.

### DESCRIPTION OF EMBODIMENTS

Next, configurations and operations of a Doherty amplifier according to an embodiment of the present invention will be described as referring to accompanying drawings.

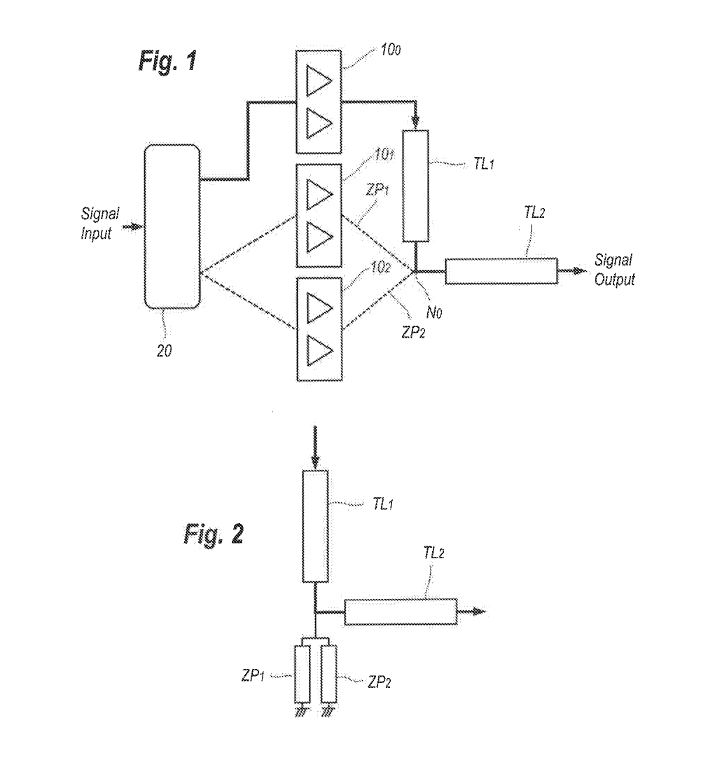

FIG. 1 shows a functional block diagram of a Doherty amplifier according to the embodiment of the present invention. A radio frequency (RF) signal entering an input terminal is evenly divided by an input power divider 20 into one carrier amplifier 10₀ and two peak amplifiers, 10₁ and 10₂. These amplifiers, 10₀ to 10₂, install two semiconductor chips therein and show performances substantially identical to each other. That is, the carrier amplifier 10₀ and the peak amplifiers, 10₁ and 10₂, are commutative each other. Also, two peak amplifiers, 10₁ and 10₂, are biased in conditions same to each other; specifically, two peak amplifiers, 10₁ and 10₂, are biased to be operated in the class B or class C.

The carrier amplifier 10₀ in the output thereof is coupled with a combining node N₀ through a transmission line TL₁ having an electrical length of π/2 radian, namely, a quarter-wavelength (λ/4) of the RF signal subject to the present Doherty amplifier, which means that the signal rotates a phase thereof by π/2 radian during the propagation on the transmission line. While, the two peak amplifiers, 10₁ and 10₂, in outputs thereof also couple with respective lines, ZP₁ and ZP₂, where the lines, ZP₁ and ZP₂, in electrical lengths thereof are unnecessary to be set in π/2 radian but impedance thereof is set higher than characteristic impedance (Z_{N0}) at the combining node N₀ and the characteristic line impedance of TL₂ (Z_{TL2}).

In an general design of a Doherty amplifier, when an RF signal is small such that a peak amplifier is turned off, which means that impedance viewing the peak amplifier at the combining node becomes substantially infinite, the carrier amplifier in an output thereof is extracted through two transmission lines, TL₁ and TL₂, each having electrical lengths of π/2 radian. Increasing the power of the input RF signal so as to turn on the peak amplifier, that is, at the back-off level, the impedance of the peak amplifier viewing from the combining node becomes substantial, and that viewing from the carrier amplifier to the combining node gradually decreases. At saturation where the carrier amplifier and the peak amplifier generate respective maximum power, the impedance viewing from the carrier amplifier to the combining node N₀ and that viewing from the peak amplifier to the combining node N₀ presents constructive impedance that may be represented by an equation of:

Z_{N0}=Z_{TL2}²/Z_{signal}_{_}ₒᵤₜ,

where Z_{signal}_{_}ₒᵤₜ is generally 50Ω but not restricted thereto.

However, increasing a size of a transistor implemented in the amplifiers, for instance, a transistor with a type of Field Effect Transistor (FET) and a gate width thereof becomes longer; a signal leak from a drain to a source of the FET due to parasitic capacitance therebetween becomes substantial even when the FET in the gate thereof is biased to turn of the FET. This signal leak becomes large not only as the FET becomes large but the RF signal in a frequency thereof becomes higher.

The lines, ZP₁ and ZP₂, coupled with the peak amplifiers, 10₁ and 10₂, having higher impedance are provided for suppressing signal leak from the drain to the source when the peak amplifiers, 10₁ and 10₂, are unable to be reliably turned off. The impedance viewing from the combining node N₀ to the peak amplifiers, 10₁ and 10₂, becomes substantial even when the peak amplifiers, 10₁ and 10₂, have sizes, or gate widths thereof, large enough and are biased so as to be turned off.

When the lines, ZP₁ and ZP₂, with the high impedance exist between the peak amplifiers, 10₁ and 10₂, and the peak amplifiers, 10₁ and 10₂, do not implement output matching circuits, the impedance configuration at the combining node N₀ becomes those shown in FIG. 2 when the carrier amplifier 10₀ and the peak amplifiers, 10₁ and 10₂, output the maximum power thereof. Under such a condition, output impedance of the amplifiers, 10₀ to 10₂, becomes small enough and one end of the transmission line TL₁ and those of the high-impedance lines, ZP₁ and ZP₂, are substantially grounded.

### Embodiment

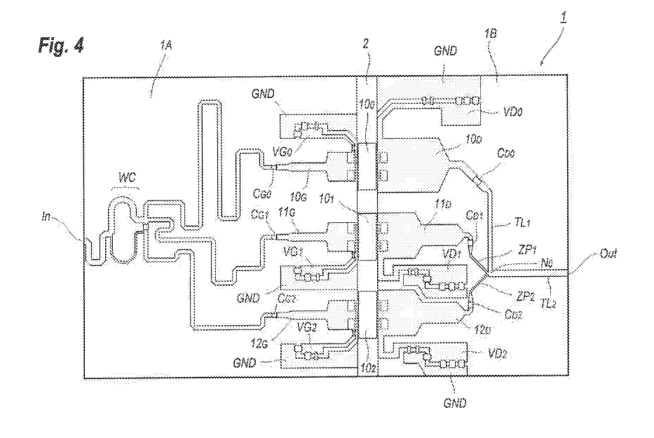

FIG. 4 is a plan view showing a layout of the Doherty amplifier 1 of the present embodiment. The Doherty amplifier 1 include three amplifiers, 10₀ to 10₂, and two layout boards, 1A and 1B, putting the three amplifies 10₀ to 10₂ therebetween, where the former layout board 1A is called as an input board, while, the latter 1B is called as an output board. The input board 1A receives an input RF signal at an input terminal In, evenly divides this input RF signal into three portions by a Wilkinson power divider WC. The carrier amplifier 10₀ and the peak amplifiers, 10₁ and 10₂, receive thus evenly divided three signals, respectively. Provided between the Wilkinson power divider WC and three amplifiers, 10₀ to 10₂, are capacitors, C_{G0} to C_{G2}, to cut DC components contained in the input signals.

The amplifiers, 10₀ to 10₂, accompany with gate patterns, 10_{G} to 12_{G}, that receive gate biases from respective gate pads, V_{G0} to V_{G2}, where the gate pads, V_{G0} to V_{G2}, are connected with the gate patterns, 10_{G} and 12_{G}, immediate to the amplifiers, 10₀ to 10₂. The gate pads, V_{G0} to V_{G2}, are accompanied with ground patterns GND and bypassing capacitors are connected between the gate pads, V_{G0} to V_{G2}, and the ground patterns GND. The ground patterns GND is electrically connected with a back metal in the input board 1A, which is grounded in a practical operation, through ground vias in the input board 1A.

In the output board 1B, the carrier amplifier 10₀ in the output thereof is extracted through an output pattern 10_{D}, to which output lead terminals of the carrier amplifier 10₀ are directly attached. The output pattern 10_{D} is coupled with a combining node N₀ through a coupling capacitor C_{D0} and the transmission line TL₁, where the coupling capacitor C_{D0} cuts DC or low frequency (LF) components contained in the signal output from the carrier amplifier 10₀; while, the transmission line TL₁ has a quarter wavelength (λ/4), that is the transmission line TL₁ is an impedance converter.

On the other hands, the peak amplifiers, 10₁ and 10₂, which also have two output lead terminals directly connected with the respective output patterns, 11_{D} and 12_{D}, are coupled with the combining node N₀ through the output patterns, 11_{D} and 12_{D}, coupling capacitors, C_{D1} and C_{D2}, and high-impedance lines, ZP₁ and ZP₂. The high-impedance lines, ZP₁ and ZP₂, are directly coupled with the combining node N₀ without interposing any conductive lines. That is, the high-impedance lines, ZP₁ and ZP₂, extend diagonally from the coupling capacitors, C_{D1} and C_{D2}, to the combining node N₀. The transmission line TL₁ also directly couples with the combining node N₀; that is, one of ends of the transmission line TL₁ is terminated at the combining node N₀. The combining node N₀ couples with the output terminal of the Doherty amplifier 1 of the present invention.

The output patterns, 10_{D} to 12_{D}, for the respective amplifies, 10₀ to 10₂, accompany with drain pads, V_{D0} to V_{D2}, to which drain biases provided to the amplifiers, 10₀ to 10₂, are supplied. The drain pads, V_{D0} to V_{D2}, also accompany many bypassing capacitors connected to the ground.

As described, the transmission line TL₁ has the quarter wavelength (λ/4) for the RF signal subject to the Doherty amplifier 1, which means that the carrier amplifier 10₀ has a substantial load greater than characteristic impedance when the peak amplifiers, 10₁ and 10₂, are turned off. On the other hand, the peak amplifiers, 10₁ and 10₂, in the outputs thereof are provided to the combining node N₀ through the high-impedance lines, ZP₁ and ZP₂. As the amplifiers, 10₀ to 10₂, installs larger transistors, for instance, a field effect transistor (FET) with a greater gate width inherently has substantial or large parasitic capacitance between a drain and a source such that the FET leaks the signal from the drain to the source even when the gate bias is supplied so as to turn off the transistor. Thus, the peak amplifiers, 10₁ and 10₂, are not practically turned off viewing from the combining node N₀.

The Doherty amplifier 1 of the present embodiment provides the high-impedance lines, ZP₁ and ZP₂, between the peak amplifiers, 10₁ and 10₂, and the combining node N₀; that is, the outputs of the peak amplifiers, 10₁ and 10₂, are provided to the combining node N₀ through the high-impedance lines, ZP₁ and ZP₂, and the impedance viewing the peak amplifiers, 10₁ and 10₂, from the combining node N₀ may be enhanced when the peak amplifiers, 10₁ and 10₂, are turned off. The outputs coming from the amplifiers, 10₀ to 10₂, to the combining node N₀ is output through the transmission line TL₂ with the quarter-wavelength (λ/4).

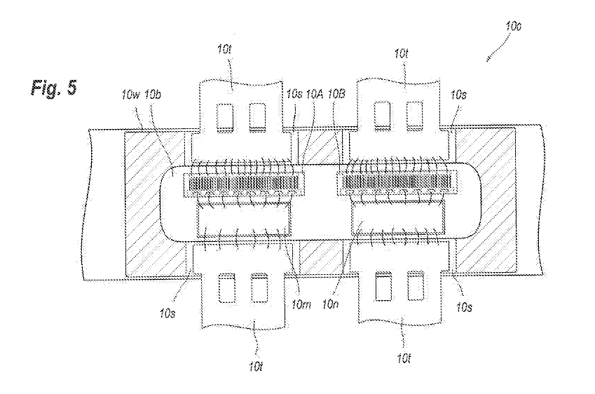

FIG. 5 shows an inside of the carrier amplifier 10₀. The explanation below concentrates on the carrier amplifier 10₀, but the peak amplifiers, 10₁ and 10₂, have the arrangement same with those shown in FIG. 5.

The carrier amplifier 10₀ implements two semiconductor chips, 10A and 10B, therein. Specifically, the carrier amplifier 10₀ includes a metal base 10b and a ceramic wall 10w, where the base 10b directly mounts the semiconductor chips 10A and 10B thereon within a space formed by the base 10b and the wall 10w. This space is air-tightly sealed by a lid that is not illustrated in FIG. 5.

The base 10b provides a pair of cuts in longitudinal ends thereof, where the cuts receive screws for fixing the amplifier on the mounting substrate 2. The ceramic wall 10w provides metalized areas 10s in a top thereof for respective terminals 10t, to which the terminals 10t are brazed there. The lid is brazed onto a hatched area on the top of the ceramic wall 10w, namely, the top except for the metalized areas 10s to air-tightly seal the semiconductor chips, 10A and 10B, within the space.

The semiconductor chips, 10A and 10B, and input matching circuits, 10m and 10n, are fixed onto the base 10b with, for instance, eutectic alloy of gold tin (AuSn), or conductive resin containing silver (Ag) filler. The semiconductor chips, 10A and 10B, each provide a plurality of fingers for electrodes of the gate, the source, and the drain. The semiconductor chips, 10A and 10B, of the present embodiment each have a total gate width of 3 mm; that is, the amplifiers, 10₀ to 10₂, have a size of 6 mm in the gate width thereof, respectively. The gate pads on the semiconductor chips, 10A and 10B, receive not only an RF signal from the terminals 10t through the input matching circuits, 10m and 10n, but the gate biases. Specifically, the input matching circuits, 10m and 10n, which has an arrangement of a die-capacitor with a top electrode and a bottom electrode. The top electrode is connected with the terminals 10t and the gate pads on the semiconductor chips, 10A and 10B, each through bonding wires; while, the bottom electrode thereof faces to and is directly bonded with the base 10b. Thus, the input matching circuits, 10m and 10n, combined with the bonding wires may constitute T-shaped LCL circuit, where L correspond to inductance attributed to the bonding wires.

On the other hand for an output of the amplifier 10₀, the drain pads of the semiconductor chips, 10A and 10B, are connected with the terminals 10t without interposing any matching circuits. This is because a transistor having a large size, or large gate width, is hard, or almost impossible, to design an adequate matching circuit because such a transistor with a large size is unable to show large impedance even when the transistor is given a bias to be turned off due to enhanced parasitic components thereof. Accordingly, the Doherty amplifier of the present embodiment provides the high-impedance lines, ZP₁ and ZP₂, between the outputs of the peak amplifiers, 10₁ and 10₂, and the combining node N₀ to enhance impedance viewing the peak amplifiers, 10₁ and 10₂, from the combining node N₀ when the output power is smaller than the back-off level. The high-impedance lines, ZP₁ and ZP₂, may realize an adequate back-off performance even when the amplifiers, 10₀ to 10₂, have an exceptionally large size such that the amplifiers, 10₀ to 10₂, show a substantial leak, or insufficient impedance when the output power of the Doherty amplifier 1 is smaller than the back-off level.

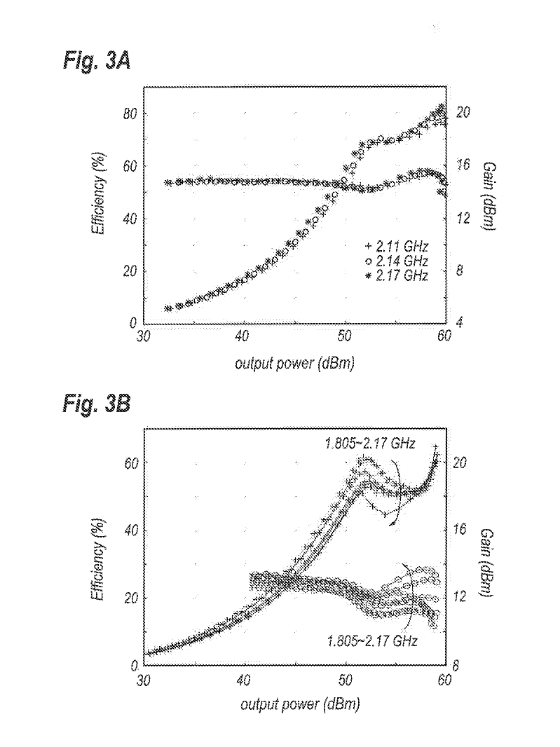

FIG. 3A shows behaviors of efficiency and gains of the Doherty amplifier of the present embodiment against the output power for the RF signal with 2.14±0.3 GHz. The Doherty amplifier of the embodiment may show the gain greater than 13 dB and maximum efficiency reaching 70% in a frequency range of 2.14±0.3 GHz and the output power of 59 dBm (around 800 W). FIG. 3B also shows behaviors of efficiency and gains of the Doherty amplifier against the output power for the RF signal whose frequencies from 1.805 to 2.17 GHz.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

I claim:

1. A Doherty amplifier that amplifies an input radio frequency (RF) signal, the Doherty amplifier having a back-off level that is smaller than a preset amount from saturated power in an output thereof, the Doherty amplifier comprising:
a carrier amplifier for amplifying the input RF signal, the carrier amplifier saturating output power thereof at the back-off level;
a peak amplifier configured to show a substantial leak when the Doherty amplifier in an output thereof is smaller than the back-off level, the peak amplifier turning on at the back-off level, and saturating an output thereof at the saturate power;
a combining node that combines an output of the carrier amplifier with the peak amplifier;
a transmission line provided between the carrier amplifier and the combining node, the transmission line having an electrical length of π/2 radian for a signal subject to the Doherty amplifier; and
an impedance line provided between the combining node and the peak amplifier,
wherein the impedance line increases impedance viewing the peak amplifier from the combining node when the Doherty amplifier in the output power thereof is smaller than the back-off level.

2. The Doherty amplifier according to claim 1,
wherein the carrier amplifier and the peak amplifier each install two semiconductor chips accompanied with lead terminals, the semiconductor chips having an arrangement substantially identical to each other and being directly connected with the lead terminals with interposing no matching circuit.

3. The Doherty amplifier according to claim 2,
wherein the semiconductor chips units each have input matching circuits independently.

4. The Doherty amplifier according to claim 1,
wherein the Doherty amplifier provides another peak amplifier and another impedance line, the peak amplifiers having characteristics substantially identical with the characteristic of the carrier amplifier, the impedance lines having impedance same to each other, and
wherein the peak amplifiers are connected with the combining node through the impedance lines, respectively.

5. The Doherty amplifier according to claim 5,
wherein the impedance lines have impedance greater than load impedance of the Doherty amplifier.
